(19) United States
(12) Patent Application Publication
(10) Pub. No.: US 2019/0137549 A1
(43) Pub. Date: May 9, 2019

(54) SYSTEMS AND METHODS FOR MULTI-TIER CENTROID CALCULATION

(71) Applicant: Velodyne LiDAR, Inc., San Jose, CA (US)

(72) Inventors: KANKE GAO, Fremont, CA (US); Kiran Kumar Gunnam, Santa Clara, CA (US); Nitinkumar Sagarbhai Barot, San Jose, CA (US)

(73) Assignee: Velodyne LiDAR, Inc., San Jose, CA (US)

(21) Appl. No.: 15/803,494

(22) Filed: Nov. 3, 2017

(51) Int. Cl. G01R 19/25; G01R 19/04; G06F 7/535

(52) U.S. Cl. CPC G01R 19/2509; G06F 7/535; G01R 19/04

(57) ABSTRACT

Described herein are systems and methods that determines a centroid of a waveform in a high noise environment. In one embodiment, the method may include determining a damping threshold and a noise-exclusion threshold for a waveform that define a three tier dynamic range for the waveform comprising a noise-exclusion region, damping region and a full region. The noise-exclusion threshold may be less than the damping threshold. Weights for each of the mass scalars may be determined based on the three tier dynamic range. The centroid may be determined based on the determined weights and their corresponding position vectors.

### BACKGROUND

### A. Technical Field

The present disclosure relates generally to systems and methods for calculating a centroid of an object, and more particularly calculating the centroid of a waveform.

### B. Background

A centroid or geometric center of a shape is the arithmetic mean (“average”) position of all the points in the shape. The definition may extend to any object in n-dimensional space; that is, the object's centroid may be the mean position of all the points in all of the coordinate directions. When the shape is a waveform, centroid analysis may include an algorithm for determining the center of energy in a pulse with a well-defined peak. For example, in a LIDAR system, the laser's transmit and return waveforms are a time-series of relative light-intensity values. LIDAR systems may have an objective of achieving an accuracy of 1 cm. For conventional methods of centroid analysis, this objective may be challenging in a high noise environment.

Accordingly, what is needed are systems and methods that provide accurate centroid estimates in a high noise environment.

### BRIEF DESCRIPTION OF THE DRAWINGS

References will be made to embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments. Items in the figures are not to scale.

FIG. 1 graphically illustrates a centroid of a waveform according to embodiments of the present document.

FIG. 2 graphically illustrates a three tier dynamic range of a waveform utilized in an “intelligent” centroid calculation according to embodiments of the present document.

FIG. 3 depicts an “intelligent” centroid calculation based on a three tier dynamic range of a waveform according to embodiments of the present document.

FIG. 4A graphically illustrates a received waveform with a damping threshold t₂ and noise-exclusion threshold t₁ indicated according to embodiments of the current disclosure.

FIG. 4B graphically illustrates a processed waveform with a damping threshold t₂ and noise-exclusion threshold t₁ indicated according to embodiments of the current disclosure.

FIG. 5 depicts a flowchart for determining a centroid of a waveform based on a three tier dynamic range of the waveform, according to embodiments of the present document.

FIG. 6A graphically illustrates an average error performance improvement based on three tier dynamic range of a waveform according to embodiments of the present disclosure.

FIG. 6B graphically illustrates RMS error performance improvement based on three tier dynamic range of a waveform according to embodiments of the present disclosure.

FIG. 7 depicts a simplified block diagram of a computing device/information handling system, in accordance with embodiments of the present document.

### DETAILED DESCRIPTION OF EMBODIMENTS

In the following description, for purposes of explanation, specific details are set forth in order to provide an understanding of the invention. It will be apparent, however, to one skilled in the art that the invention can be practiced without these details. Furthermore, one skilled in the art will recognize that embodiments of the present invention, described below, may be implemented in a variety of ways, such as a process, an apparatus, a system, a device, or a method on a tangible computer-readable medium.

Components, or modules, shown in diagrams are illustrative of exemplary embodiments of the invention and are meant to avoid obscuring the invention. It shall also be understood that throughout this discussion that components may be described as separate functional units, which may comprise sub-units, but those skilled in the art will recognize that various components, or portions thereof, may be divided into separate components or may be integrated together, including integrated within a single system or component. It should be noted that functions or operations discussed herein may be implemented as components. Components may be implemented in software, hardware, or a combination thereof. Hardware may include electronic components and circuitry.

Furthermore, connections between components or systems within the figures are not intended to be limited to direct connections. Rather, data between these components may be modified, re-formatted, or otherwise changed by intermediary components. Also, additional or fewer connections may be used. It shall also be noted that the terms “coupled,” “connected,” or “communicatively coupled” shall be understood to include direct connections, indirect connections through one or more intermediary devices, and wireless connections.

Reference in the specification to “one embodiment,” “preferred embodiment,” “an embodiment,” or “embodiments” means that a particular feature, structure, characteristic, or function described in connection with the embodiment is included in at least one embodiment of the invention and may be in more than one embodiment. Also, the appearances of the above-noted phrases in various places in the specification are not necessarily all referring to the same embodiment or embodiments.

The use of certain terms in various places in the specification is for illustration and should not be construed as limiting. A service, function, or resource is not limited to a single service, function, or resource; usage of these terms may refer to a grouping of related services, functions, or resources, which may be distributed or aggregated.

The terms “include,” “including,” “comprise,” and “comprising” shall be understood to be open terms and any lists the follow are examples and not meant to be limited to the listed items. Any headings used herein are for organizational purposes only and shall not be used to limit the scope of the description or the claims. Each reference mentioned in this patent document is incorporate by reference herein in its entirety.

Furthermore, one skilled in the art shall recognize that: (1) certain steps may optionally be performed; (2) steps may not be limited to the specific order set forth herein; (3) certain steps may be performed in different orders; and (4) certain steps may be done concurrently.

### A. Centroid Calculation

A centroid may be calculated based on the position vectors and mass scalars associated with the corresponding position vectors. An objective may be the development of an algorithm that accurately calculates the centroid of position vectors under conditions of certain levels of noise. For a waveform, a mass scalar may represent the signal strength of the waveform or relative intensity of a waveform.

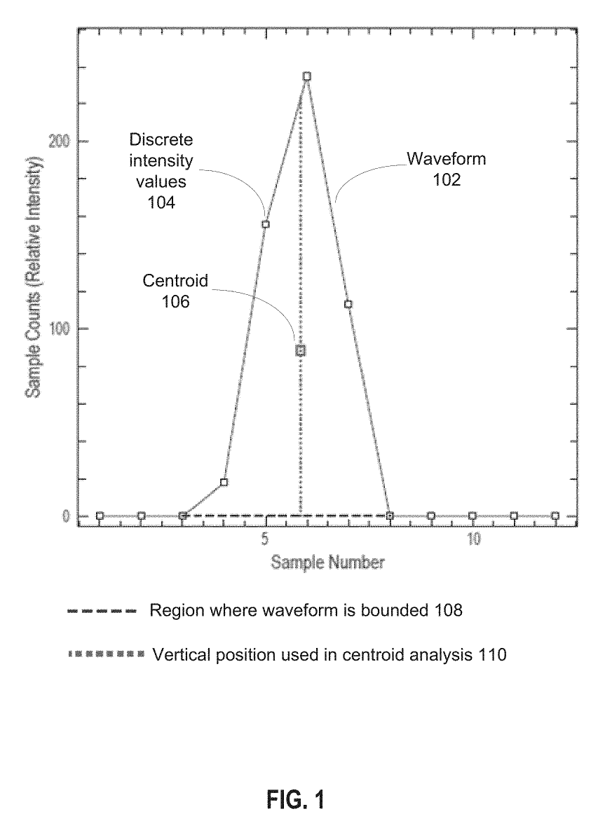

The centroid of a waveform may be visualized as the point in space on which a waveform may be balanced relative to its shape. FIG. 1 illustrates a graphic 100 of a centroid 106 in waveform 102 according to embodiments of the present document. Waveform 102 may represent a return signal to a LIDAR system. Waveform 102 may be displayed relative the relative intensity (y-axis) and the sample count (x-axis). The dotted line 108 indicates the region where waveform 102 is bounded, or in other words, the width of waveform 102. Waveform 102 may be sampled multiple times obtain corresponding relative intensity/sample count (x,y) values. FIG. 1 illustrates that waveform 102 may be sampled at sample number 1, 3, 5, 7, 9, 11, as indicated by discrete intensity values 104. The sample information may provide inputs for a centroid calculation that may determine the position of centroid 106 in waveform 102. The vertical position 110 used in the centroid analysis is indicated in FIG. 1. The sample count may be considered a position vector.

One method for a centroid calculation comprises a weighted sum algorithm based on the mass scalars and position vectors:

$$centroid = \frac{{Σ}_{i} {p}_{i} * {m}_{i}}{{Σ}_{i} {m}_{i}} \qquad ( 1 )$$

where pᵢ is position vector and mᵢ is mass scalar for i-th entry (or i-th sample).

The aforementioned algorithm may provide acceptable accuracy for estimating a centroid in a low noise environment. In a high noise environment and with low S/N ratios (SNR), the accuracy of the estimated centroid may decrease. This issue may cause a corresponding reduction in accuracy in a light detection system, for example, but without limitation, a LIDAR system. Although it may not be possible to reduce the noise, it may be desirable to utilize an “intelligent” centroid calculation to remove a noise bias and minimize the impact of noise in order to improve the accuracy of the centroid estimation.

### B. Three-Tier Centroid Calculation

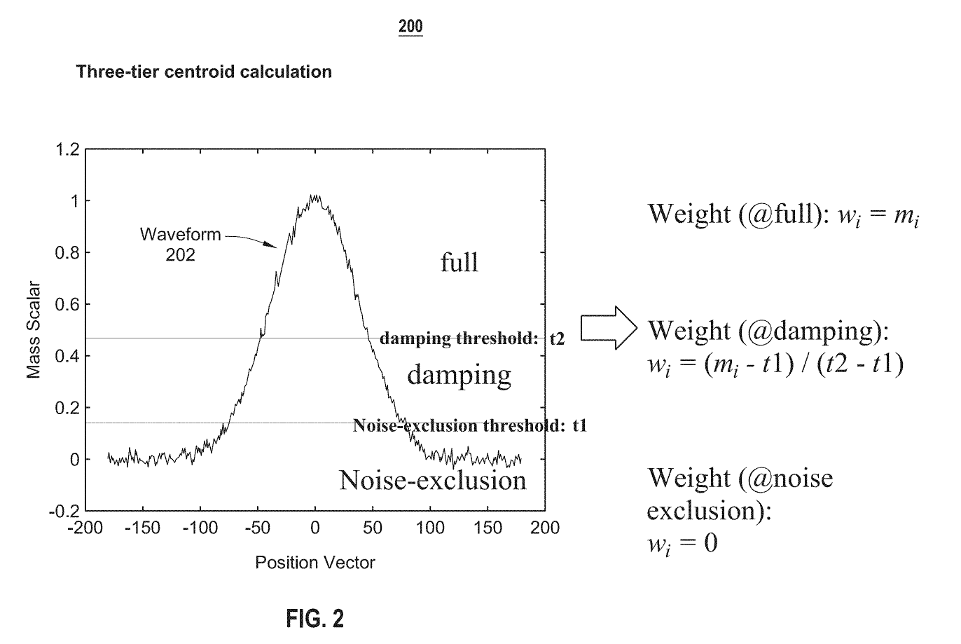

In order to reduce the impact of noise, the dynamic range of a signal or waveform may be divided into three tiers: noise-exclusion region, damping region and full region. FIG. 2 graphically illustrates a three tier dynamic range 200 of waveform 202 that may be utilized in an “intelligent” centroid calculation according to embodiments of the present document. The concept is to determine a weight of the i-th mass scalar (mᵢ) based on the value of the i-th mass scalar and based on the three-tier structure of dynamic range for waveform 202. The method may suppress the impact of noise in calculating the centroid. One skilled in the art will recognize that the dynamic range of a signal or waveform may be divided into more than three-tiers and allow a multi-tier centroid calculation, where the number of tiers is greater than three.

Generally, noise in the noise-exclusion region may dominate (i.e. low S/N ratios), so inclusion of the mass scalars in the centroid calculation may not be beneficial. In the damping region, there may be a level of noise, but there still may be useful information in the mass scalars. In the full region, there may be high S/N ratios and it may be beneficial to include the full value of the mass scalar in the centroid calculation.

The three tier dynamic range of waveform 202 maybe defined based on the following thresholds: 1) noise-exclusion threshold t₁, and 2) damping threshold t₂. The i-th sample may include the i-th mass scalar or mᵢ. The location of the i-th mass scalar may be determined as follows:

If the i-th mass scalar is less than t₁, the i-th mass scalar may be located in the noise-exclusion region.

If the i-th mass scalar is more than t₁, but less than t₂, the i-th mass scalar may be located in the damping region.

If the i-th mass scalar is more than t₂, the i-th mass scalar may be located in the full region.

The noise-exclusion region may include a significant noise environment relative to the signal strength of the waveform. Per FIG. 2, in the noise-exclusion region, the value of the mass scalar, i.e., signal strength, has a relative intensity of less than 0.2. It may be beneficial for the centroid calculation to minimize the weight of mass scalars in the noise-exclusion region in order to minimize the negative impact of the high noise environment. In one embodiment for the noise-exclusion region: Weight (@noise exclusion): wᵢ=0, where wᵢ is the weight of the i-th mass scalar. One skilled in the art will recognize that the noise-exclusion threshold may vary based on the application and environment in which embodiments of the invention are implemented, all of which are intended to fall under the scope of the invention.

In the damping region, a damping factor is assigned to obtain a balance between the information of the mass scalars and the negative impact of the noise environment. In one embodiment for the damping region, neither factor may dominate. In another embodiment for the damping region: Weight (@damping): wᵢ=(mᵢ−t₁)/(t₂−t₁), where wᵢ is the weight of the i-th mass scalar, mᵢ, i.e., the i-th sample of waveform 202, and t₁ and t₂ are the noise-exclusion threshold and damping threshold, respectively. One skilled in the art will recognize that the damping threshold may vary based on the application and environment in which embodiments of the invention are implemented, all of which are intended to fall under the scope of the invention.

In the full region, there may be a minimal noise environment and/or high S/N ratios. It may be beneficial to maintain the weight values for the i-th mass scalar in this region. In one embodiment for the full region: Weight (@full): wᵢ=mᵢ.

The mass scalars of the waveform located in the full region have a greater S/N ratio than the mass scalars of the waveform located in the damping region. The mass scalars of the waveform located in the damping region have a greater S/N ratio than the mass scalars of the waveform located in the noise-exclusion region.

A centroid maybe calculated based on an algorithm that utilizes the three-tier regions as follows:

$$C = \frac{{Σ}_{i} {p}_{i} * {w}_{i}}{{Σ}_{i} {w}_{i}} \qquad ( 2 )$$

where wᵢ is defined for the three-tier regions as discussed herein, pᵢ is the position vector for the i-th sample (or i-th entry).

The noise-exclusion threshold t₁ and damping threshold t₂ may be determined based on an analysis of the noise environment. During the period of time for the calculation of the centroid, the noise-exclusion threshold t₁ and damping threshold t₂ may be static or may be dynamically adjusted based on the noise environment analysis.

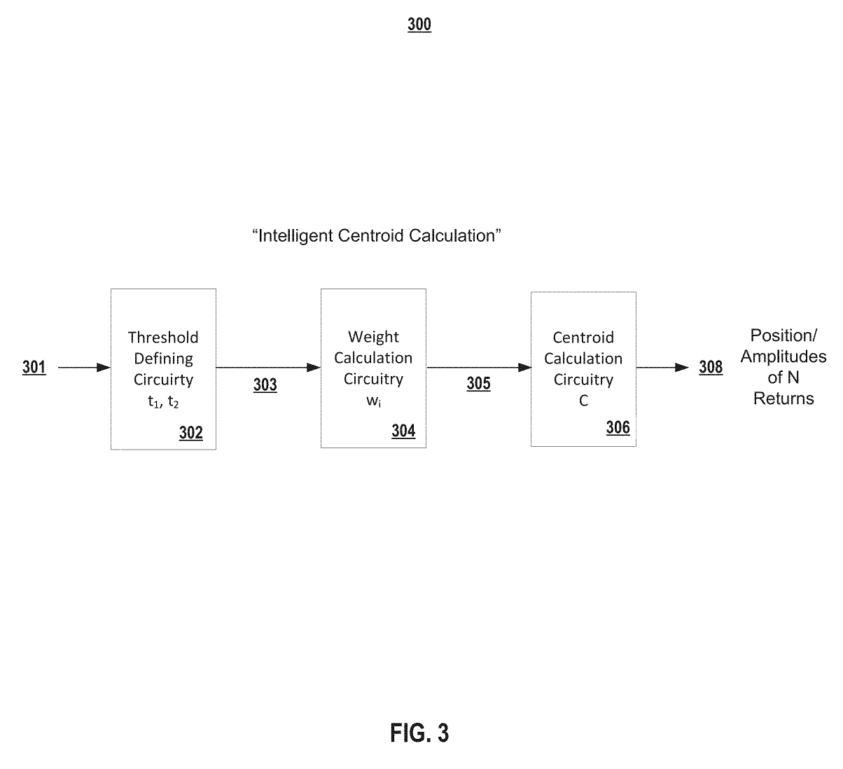

FIG. 3 depicts an “intelligent” centroid calculation 300 based on the three tier dynamic range of a waveform according to embodiments of the present document. The “intelligent” centroid calculation 300 may comprise threshold defining circuitry 302, weight calculation circuitry 304 and centroid calculation circuitry 306. Waveform 301, which may be equivalent to waveform 202 of FIG. 2, may be coupled to an input of threshold defining circuitry 302. In some embodiments, waveform 301 may be an output of a peak detector of a LIDAR system. The term “circuitry” is intended to cover a hardware implementation/acceleration of a process, a software implementation in which software code is implemented and executed using circuitry such as those being found in processors or application specific hardware, or a combination thereof.

Threshold defining circuitry 302 may determine the values of noise-exclusion threshold t₁ and damping threshold t₂. Noise-exclusion threshold t₁ may be based on three options based on White Gaussian noise (AWGN): noise sigma values of 3, 4 or 5. Damping threshold t₂ may be based on four options: 0.3, 0.4, 0.5 or 0.6, where these values are normalized to one. A sweep analysis is performed for combinations of t₁ and t₂ in order to determine the noise-exclusion threshold t₁ and damping threshold t₂ with a preferred performance. During the period of time of the calculation of the centroid, the noise-exclusion threshold t₁ and damping threshold t₂ may be static or may be dynamically adjusted based on the noise environment analysis.

The determined values of noise-exclusion threshold t₁ and damping threshold t₂ are coupled via waveform 303 to weight calculation circuitry 304. The weight for the i-th mass scalar in the noise-exclusion region may be calculated by weight calculation circuitry 304: Weight (@noise exclusion): wᵢ=0, where mᵢ represents the mass scalar of the i-th sample. The weight for the i-th mass scalar in the full region may be calculated by weight calculation circuitry 304: Weight (@ full): wᵢ=mᵢ, where mᵢ represents the mass scalar of the i-th sample. Weight (@damping): wᵢ=(mᵢ−t₁)/(t₂−t₁), where wᵢ is the weight of the i-th mass scalar, mᵢ.

The weight calculation circuitry 304 may generate a processed waveform 305, comprising the weights calculations for the mass scalars in the three tier regions. Processed waveform 305 may be coupled to centroid calculation circuitry 306. In turn, centroid calculation circuitry 306 may execute algorithm (2) and provide an estimate of the centroid via output 308. In a LIDAR system, output 308 may comprise the position and amplitude of a return signal.

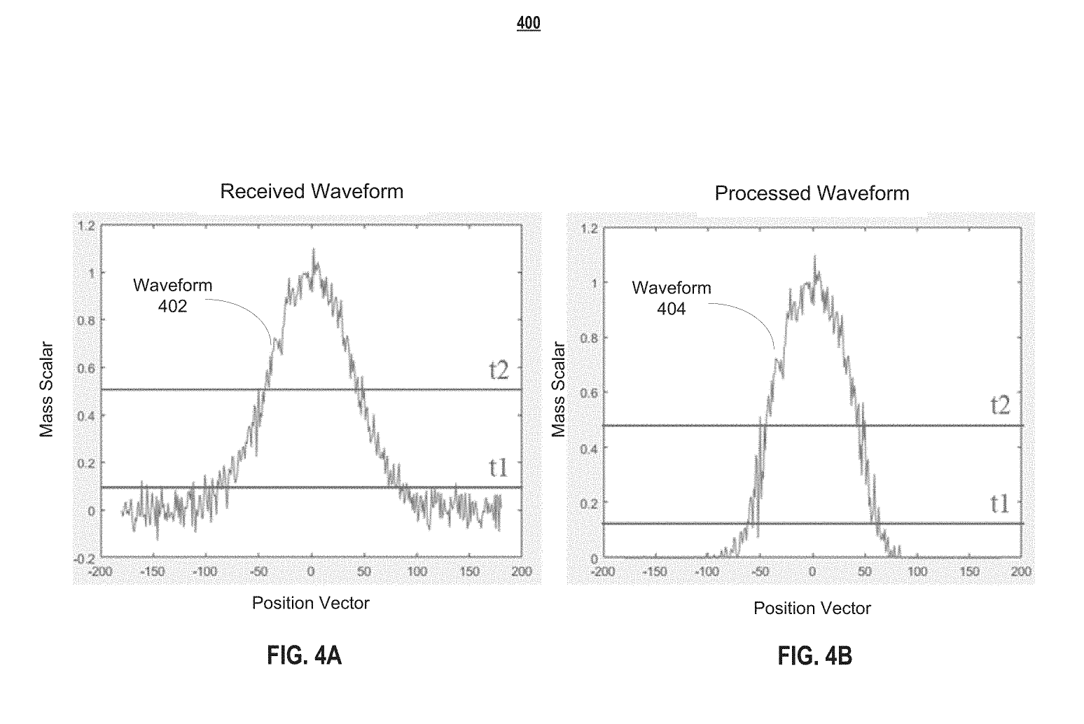

FIG. 4A graphically illustrates in sheet 400 a received waveform 402 with a damping threshold t₂ and noise-exclusion threshold t₁ indicated according to embodiments of the current disclosure. Received waveform 402 may represent waveform 301 of FIG. 3. Per FIG. 4A, noise-exclusion threshold t₁ may be set a level of approximately 0.1 to exclude mass scalars of received waveform 402 in a high noise environment. As illustrated, this action may exclude entries with position vectors having values greater than approximately 100, or less than approximately −100. With these settings for noise-exclusion threshold t₁, noise of the received waveform 402 may be suppressed. Per FIG. 4A, a damping threshold t₂ may be set at a level of approximately 0.5 to allow a balance between information of the mass scalars and information loss due to noise in the damping region.

FIG. 4B graphically illustrates in sheet 400 a processed waveform 404 with a damping threshold t₂ and noise-exclusion threshold t₁ indicated according to embodiments of the current disclosure. Per FIG. 4B, processed waveform 404 may comprise a peak with a slope sharper than the slope of received waveform 402, and may comprise a noise environment less than in received waveform 402. Effectively, the processed waveform 404 reflects the “weighting” of the mass scalars. Processed waveform 404 may provide a more accurate estimate of the centroid of received waveform 402. Processed waveform 404 may represent the processed waveform 305, which is the output of weight calculation circuitry 304.

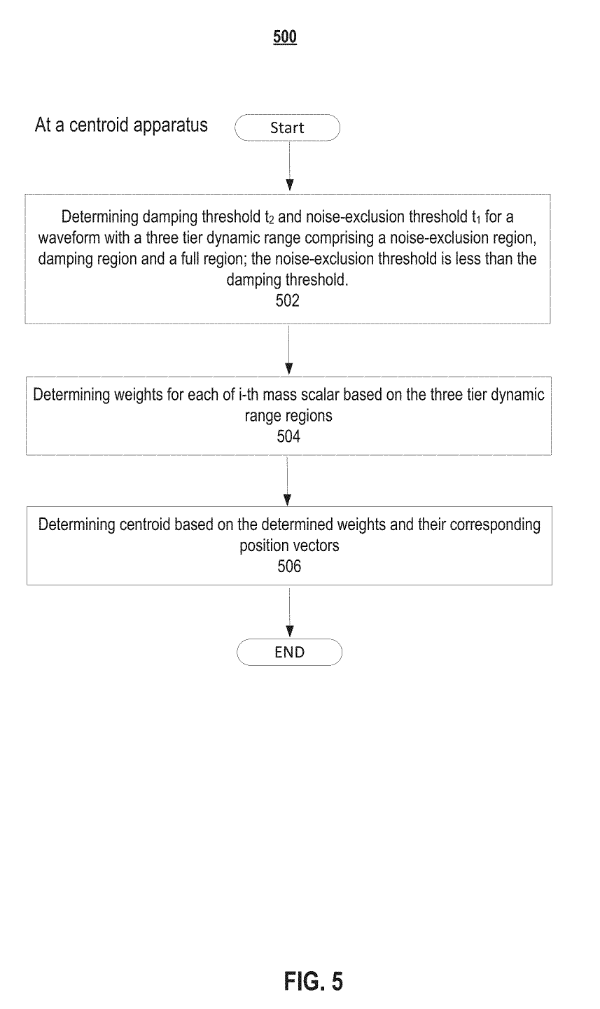

FIG. 5 depicts a flowchart 500 for determining a centroid of a waveform based on a three tier dynamic range of the waveform, according to embodiments of the present document. The method comprises the steps of: 1) Determining damping threshold t₂ and noise-exclusion threshold t₁ for a waveform with a three tier dynamic range comprising a noise-exclusion region, damping region and a full region; the noise-exclusion threshold may be less than the damping threshold. (step 502); 2) Determining weights for each of i-th mass scalar entries based on the three tier dynamic range regions. (step 504); and 3) Determining centroid based on the determined weights and their corresponding position vectors. (step 506)

### C. Results

It shall be noted that these experiments and results are provided by way of illustration and were performed under specific conditions using a specific embodiment or embodiments; accordingly, neither these experiments nor their results shall be used to limit the scope of the disclosure of the current patent document.

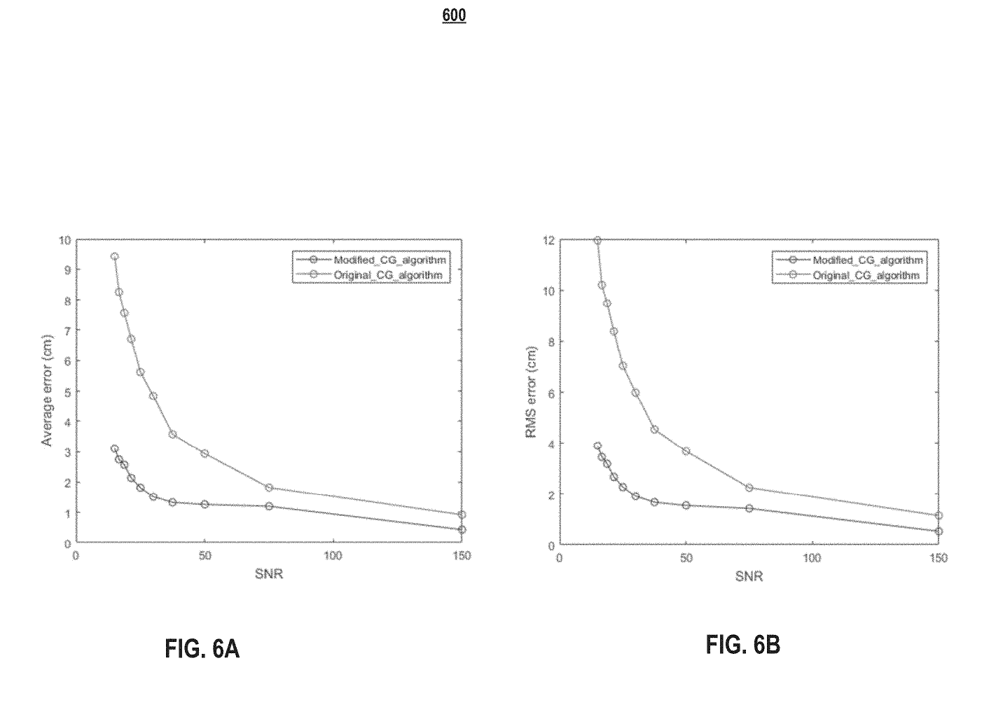

FIG. 6A graphically illustrates in sheet 600 the average error performance improvements based on three tier dynamic range of a waveform according to embodiments of the present disclosure. As indicated, the average error (cm) for the Original_CG_algorithm (algorithm (1)) is greater than the average error (cm) for the Modified_CG_algorithm (algorithm (2)), especially at lower SNR values.

FIG. 6B graphically illustrates in sheet 600 the RMS error performance improvement based on three tier dynamic range of a waveform according to embodiments of the present disclosure. As indicated, the RMS error (cm) for the Original_CG_algorithm (algorithm (1)) is greater than the RMS error (cm) for the Modified_CG_algorithm (algorithm (2)), especially at lower SNR values.

### D. Summary

A method for calculating a centroid of a waveform may comprise: determining, at a centroid apparatus, a damping threshold and a noise-exclusion threshold for a waveform that define a three tier dynamic range for the waveform comprising a noise-exclusion region, damping region and a full region, wherein the noise-exclusion threshold is less than the damping threshold; determining, at the centroid apparatus, weights for each of i-th mass scalar based on the three tier dynamic range; and determining, at the centroid apparatus, a centroid based on the determined weights and their corresponding position vectors.

Additionally, the centroid of the waveform may comprise a sum of a multiplication of an i-th position vector of and a weight of the i-th mass scalar, divided by a sum of the of the weights of the mass scalars. If the i-th mass scalar is less than the damping threshold, but greater than the noise-exclusion threshold, the determined weight of the i-th mass scalar is equal to a difference between the i-th mass scalar and the noise-exclusion threshold, divided by the difference between the damping threshold and the noise-exclusion threshold. If the i-th mass scalar is greater than the damping threshold, the determined weight of the i-th mass scalar is equal to the i-th mass scalar. If the i-th mass scalar is less than the noise-exclusion threshold, the determined weight of the i-th mass scalar is equal to zero.

Further, the damping region may comprise mass scalars having values greater than the noise-exclusion threshold and less than the damping threshold; the full regions comprises mass scalars having values greater than the damping threshold; and the noise-exclusion region comprises mass scalars having values less than the damping threshold. The mass scalars of the waveform located in the full region have a greater the S/N ratio than the mass scalars of the waveform located in the damping region. The mass scalars of the waveform located in the damping region have a greater the S/N ratio than the mass scalars of the waveform located in the noise-exclusion region. The damping threshold and the noise-exclusion threshold for the waveform are dynamically adjusted while determining the centroid.

In another embodiment, an apparatus for calculating a centroid for a waveform may comprise a threshold defining circuitry operable to determine a noise-exclusion threshold and a damping threshold for a waveform, wherein the noise-exclusion threshold is less than the damping threshold; a weight calculation circuitry operable to determine weights of mass scalars of the waveform based on the noise-exclusion threshold, the damping threshold and mass scalar values; and centroid calculation circuitry operable to determine a centroid of the waveform based on determined weights of mass scalars and their corresponding position vectors. The centroid of the waveform comprises a sum of a multiplication of an i-th position vector and a determined weight of an i-th mass scalar, divided by the sum of the determined weights of the mass scalars.

If an i-th mass scalar is less than the damping threshold, but greater than the noise-exclusion threshold, a determined weight of the i-th mass scalars is equal to a difference between the i-th mass scalar and the noise-exclusion threshold, divided by a difference between the damping threshold and the noise-exclusion threshold. If an i-th mass scalar is greater than the damping threshold, a determined weight of the i-th mass scalar is equal to the value of the i-th mass scalar. If an i-th mass scalar is less than the noise-exclusion threshold, a determined weight of the i-th mass scalar is equal to zero.

### E. System Embodiments

In embodiments, aspects of the present patent document may be directed to or implemented on information handling systems/computing systems. For purposes of this disclosure, a computing system may include any instrumentality or aggregate of instrumentalities operable to compute, calculate, determine, classify, process, transmit, receive, retrieve, originate, route, switch, store, display, communicate, manifest, detect, record, reproduce, handle, or utilize any form of information, intelligence, or data for business, scientific, control, or other purposes. For example, a computing system may be a LIDAR device, personal computer (e.g., laptop), tablet computer, phablet, personal digital assistant (PDA), smart phone, smart watch, or any other suitable device and may vary in size, shape, performance, functionality, and price. The computing system may include random access memory (RAM), one or more processing resources such as a central processing unit (CPU) or hardware or software control logic, ROM, and/or other types of memory. Additional components of the computing system may include one or more memory devices, one or more network ports for communicating with external devices as well as various input and output (I/O) devices, such as a touchscreen and/or a video display. The computing system may also include one or more buses operable to transmit communications between the various hardware components.

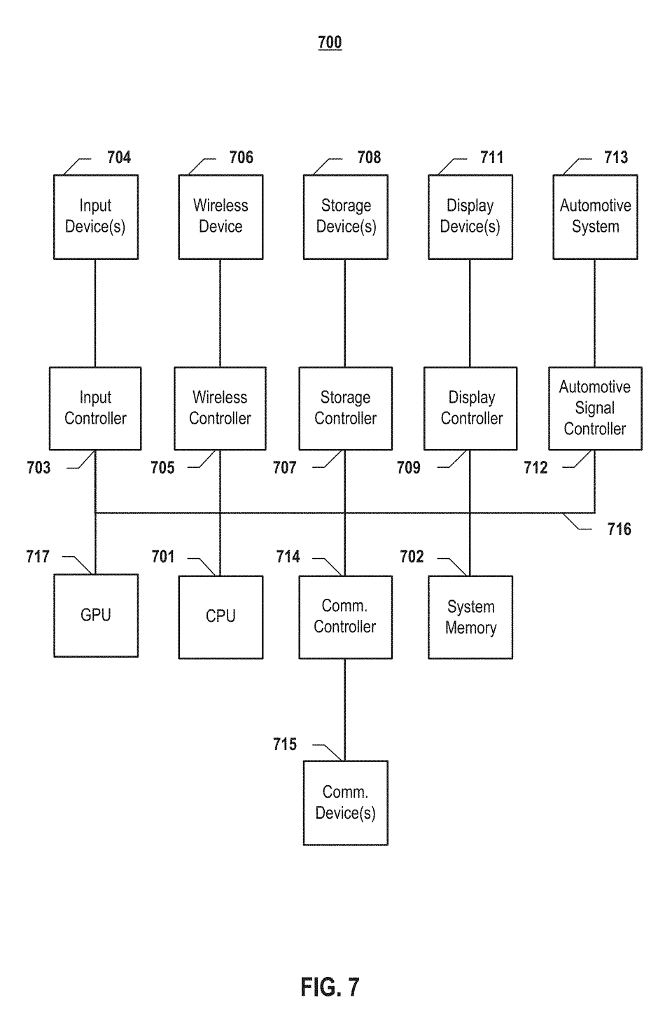

FIG. 7 depicts a simplified block diagram of a computing device/information handling system (or computing system) according to embodiments of the present disclosure. It will be understood that the functionalities shown for system 700 may operate to support various embodiments of an information handling system—although it shall be understood that an information handling system may be differently configured and include different components.

As illustrated in FIG. 7, system 700 includes one or more central processing units (CPU) 701 that provides computing resources and controls the computing device. CPU 701 may be implemented with a microprocessor or the like, and may also include one or more graphics processing units (GPU) 717 and/or a floating point coprocessor for mathematical computations or any other type of coprocessor. System 700 may also include a system memory 702, which may be in the form of random-access memory (RAM), read-only memory (ROM), or both.

A number of controllers and peripheral devices may also be provided, as shown in FIG. 7. An input controller 703 represents an interface to various input device(s) 704, such as a keyboard, mouse, or stylus. There may also be a wireless controller 705, which communicates with a wireless device 706. System 700 may also include a storage controller 707 for interfacing with one or more storage devices 708 each of which includes various types of storage medium. Storage device(s) 708 may also be used to store processed data or data to be processed in accordance with the invention. System 700 may also include a display controller 709 for providing an interface to a display device 711. The computing system 700 may also include an automotive signal controller 712 for communicating with a one or more automotive systems (e.g., autonomous driving system) 713. A communications controller 714 may interface with one or more communication devices 715, which enables system 700 to connect to remote devices through any of a variety of networks including the Internet, a cloud resource (e.g., an Ethernet cloud, an Fiber Channel over Ethernet (FCoE)/Data Center Bridging (DCB) cloud, etc.), a local area network (LAN), a wide area network (WAN), a storage area network (SAN) or through any suitable electromagnetic carrier signals including infrared signals.

In the illustrated system, all major system components may connect to a bus 716, which may represent more than one physical bus. However, various system components may or may not be in physical proximity to one another. For example, input data and/or output data may be remotely transmitted from one physical location to another. In addition, programs that implement various aspects of this invention may be accessed from a remote location (e.g., a server) over a network. Such data and/or programs may be conveyed through any of a variety of machine-readable medium including, but are not limited to: magnetic media such as hard disks, floppy disks, and magnetic tape; optical media such as CD-ROMs and holographic devices; magneto-optical media; and hardware devices that are specially configured to store or to store and execute program code, such as application specific integrated circuits (ASICs), programmable logic devices (PLDs), flash memory devices, and ROM and RAM devices.

Embodiments of the present invention may be encoded upon one or more non-transitory computer-readable media with instructions for one or more processors or processing units to cause steps to be performed. It shall be noted that the one or more non-transitory computer-readable media shall include volatile and non-volatile memory. It shall be noted that alternative implementations are possible, including a hardware implementation or a software/hardware implementation. Hardware-implemented functions may be realized using ASIC(s), programmable arrays, digital signal processing circuitry, or the like. Accordingly, the “means” terms in any claims are intended to cover both software and hardware implementations. Similarly, the term “computer-readable medium or media” as used herein includes software and/or hardware having a program of instructions embodied thereon, or a combination thereof. With these implementation alternatives in mind, it is to be understood that the figures and accompanying description provide the functional information one skilled in the art would require to write program code (i.e., software) and/or to fabricate circuits (i.e., hardware) to perform the processing required.

It shall be noted that embodiments of the present invention may further relate to computer products with a non-transitory, tangible computer-readable medium that have computer code thereon for performing various computer-implemented operations. The media and computer code may be those specially designed and constructed for the purposes of the present invention, or they may be of the kind known or available to those having skill in the relevant arts. Examples of tangible computer-readable media include, but are not limited to: magnetic media such as hard disks, floppy disks, and magnetic tape; optical media such as CD-ROMs and holographic devices; magneto-optical media; and hardware devices that are specially configured to store or to store and execute program code, such as application specific integrated circuits (ASICs), programmable logic devices (PLDs), flash memory devices, and ROM and RAM devices. Examples of computer code include machine code, such as produced by a compiler, and files containing higher level code that are executed by a computer using an interpreter. Embodiments of the present invention may be implemented in whole or in part as machine-executable instructions that may be in program modules that are executed by a processing device. Examples of program modules include libraries, programs, routines, objects, components, and data structures. In distributed computing environments, program modules may be physically located in settings that are local, remote, or both.

One skilled in the art will recognize no computing system or programming language is critical to the practice of the present invention. One skilled in the art will also recognize that a number of the elements described above may be physically and/or functionally separated into sub-modules or combined together.

It will be appreciated to those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claims may be arranged differently including having multiple dependencies, configurations, and combinations.

What is claimed is:

1. An apparatus comprising:
a threshold defining circuitry operable to determine a noise-exclusion threshold and a damping threshold for a waveform, wherein the noise-exclusion threshold is less than the damping threshold;
a weight calculation circuitry operable to determine weights of mass scalars of the waveform based on the noise-exclusion threshold, the damping threshold and mass scalar values; and
a centroid calculation circuitry operable to determine a centroid of the waveform based on determined weights of mass scalars and their corresponding position vectors.

2. The apparatus of claim 1, wherein,
the centroid of the waveform comprises a sum of a multiplication of an i-th position vector and a determined weight of an i-th mass scalar, divided by the sum of the determined weights of the mass scalars.

3. The apparatus of claim 1, wherein,
if an i-th mass scalar is less than the damping threshold, but greater than the noise-exclusion threshold, a determined weight of the i-th mass scalars is equal to a difference between the i-th mass scalar and the noise-exclusion threshold, divided by a difference between the damping threshold and the noise-exclusion threshold.

4. The apparatus of claim 1, wherein,
if an i-th mass scalar is greater than the damping threshold, a determined weight of the i-th mass scalar is equal to a value of the i-th mass scalar.

5. The apparatus of claim 1, wherein,
if an i-th mass scalar is less than the noise-exclusion threshold, a determined weight of the i-th mass scalar is equal to zero.

6. The apparatus of claim 1, wherein,
a damping region comprises mass scalars having values greater than the noise-exclusion threshold and less than the damping threshold,
a full region comprises mass scalars having values greater than the damping threshold, and
a noise-exclusion region comprises mass scalar having values less than the damping threshold.

7. The apparatus of claim 6, wherein,
the mass scalars of the waveform located in the full region have a greater S/N ratio than the mass scalars of the waveform located in the damping region.

8. The apparatus of claim 6, wherein,
the mass scalars of the waveform located in the damping region have a greater S/N ratio than the mass scalars of the waveform located in the noise-exclusion region.

9. A method comprising:
determining, at a centroid apparatus, a damping threshold and a noise-exclusion threshold for a waveform that define a three tier dynamic range for the waveform comprising a noise-exclusion region, a damping region and a full region, wherein the noise-exclusion threshold is less than the damping threshold;
determining, at the centroid apparatus, weights for each of mass scalars of the waveform based on the three tier dynamic range; and
determining, at the centroid apparatus, a centroid based on the determined weights and their corresponding position vectors.

10. The method of claim 9, wherein,
the centroid of the waveform comprises a sum of a multiplication of an i-th position vector of and a determined weight of an i-th mass scalar, divided by a sum of the determined weights of the mass scalars.

11. The method of claim 9, wherein,
if an i-th mass scalar is less than the damping threshold, but greater than the noise-exclusion threshold, a determined weight of the i-th mass scalar is equal to a difference between the i-th mass scalar and the noise-exclusion threshold, divided by the difference between the damping threshold and the noise-exclusion threshold.

12. The method of claim 9, wherein,
if an i-th mass scalar is greater than the damping threshold, a determined weight of the i-th mass scalar is equal to the i-th mass scalar.

13. The method of claim 9, wherein,
if an i-th mass scalar is less than the noise-exclusion threshold, a determined weight of the i-th mass scalar is equal to zero.

14. The method of claim 9, wherein,
the damping region comprises mass scalars having values greater than the noise-exclusion threshold and less than the damping threshold,
the full region comprises mass scalars having values greater than the damping threshold, and
the noise-exclusion region comprises mass scalars having values less than the damping threshold.

15. The method of claim 9, wherein,
the mass scalars of the waveform located in the full region have a greater S/N ratio than the mass scalars of the waveform located in the damping region.

16. The method of claim 9, wherein,
the mass scalars of the waveform located in the damping region have a greater S/N ratio than the mass scalars of the waveform located in the noise-exclusion region.

17. The method of claim 9, wherein, the damping threshold and the noise-exclusion threshold for the waveform are dynamically adjusted while determining the centroid.

18. A non-transitory computer readable storage medium having computer program code stored thereon, the computer program code, when executed by one or more processors implemented on an centroid apparatus, causes the centroid apparatus to perform a method comprising:
determining a damping threshold and a noise-exclusion threshold for a waveform that define a three tier dynamic range for the waveform comprising a noise-exclusion region, damping region and a full region, wherein the noise-exclusion threshold is less than the damping threshold;
determining weights for each of mass scalars of the waveform based on the three tier dynamic range; and
determining, a centroid based on the determined weights and their corresponding position vectors.

19. The method of claim 18, wherein,
the centroid of the waveform comprises a sum of a multiplication of an i-th position vector and a determined weight of an i-th mass scalar, divided by the sum of the determined weights of the mass scalars.

20. The method of claim 18, wherein, the damping threshold and the noise-exclusion threshold for the waveform are dynamically adjusted while determining the centroid.
